(19) United States
(12) Patent Application Publication
(10) Pub. No.: US 2021/0351311 A1
(43) Pub. Date: Nov. 11, 2021

(54) FLEXIBLE LAMINATE OF PHOTOVOLTAIC CELLS AND ASSOCIATED PRODUCTION METHOD

(71) Applicant: TOTAL SE, Courbevoie (FR)

(72) Inventors: Valérick CASSAGNE, Limours (FR); Frédéric LEROY, Vincennes (FR); Martin SANDER, Palaiseau (FR)

(21) Appl. No.: 17/278,227

(22) PCT Filed: Sep. 19, 2019
(86) PCT No.: PCT/EP2019/075260

§ 371 Date: Mar. 19, 2021

(30) Foreign Application Priority Data
Sep. 22, 2018 (FR) 1858617

(51) Int. Cl. H01L 31/048; H01L 31/024

(52) U.S. Cl. CPC H01L 31/0488; H01L 31/024; H01L 31/0481

(57) ABSTRACT

The present invention relates to a flexible laminate (1) of photovoltaic cells, comprising at least: —a layer of interconnected photovoltaic cells (3); and —a front layer (5) and a back layer (7) for encapsulating the layer of photovoltaic cells (3), said front encapsulation layer (5) and said back encapsulation layer (7) sandwiching the layer of photovoltaic cells (3), the front encapsulation layer (5) comprises at least one glass fiber fabric (51) and at least a first encapsulation resin (53) that comprises at least one polyolefin, and the back encapsulation layer (7) comprises at least one glass fiber fabric (71) and a second encapsulation resin (73). The present invention also relates to a method for producing such a flexible laminate (1).

### TECHNICAL FIELD OF THE INVENTION

The present invention relates to the field of photovoltaic modules. More particularly, the present invention relates to laminated photovoltaic modules. Furthermore, the present invention also relates to a method for producing such a flexible laminate forming the photovoltaic module.

### BACKGROUND OF THE INVENTION

Due to the reduction in the stock of fossil fuels and the increase in pollution generated by the consumption of these fossil fuels, we are increasingly turning to renewable energy resources and energy consumption in a logic of sustainable development. This trend naturally leads to favoring renewable energies such as solar energy. It is now conventional to install photovoltaic panels, in particular on the roofs of businesses, public buildings, or simply on the roofs of private homes to supply power to the devices of the home in question.

The photovoltaic modules have to be made thin enough to limit their weight and size, which makes it possible, for example, for them to be installed on board a vehicle, to be integrated into the structure of a vehicle, or to be integrated into lightweight structures of buildings. In order to adapt to very diverse locations and to operate while being subjected to climatic aggressions, vibrations and mechanical stresses in general over long periods, sometimes more than twenty years, the modules thus have to have a sufficiently strong structure while being lightweight. To resolve these constraints, it is known to encapsulate photovoltaic cells in encapsulation layers that include a polymerizable resin, in order to ensure the connection between the different layers making up the photovoltaic module without the glass plate that is usual for standard modules and increases the weight of the photovoltaic module. In this way, the photovoltaic cells are protected as much from a mechanical perspective as from external conditions, air, water and ultraviolet radiation.

In addition, the shape of the support can vary significantly, in particular have a curved receiving surface. It is therefore necessary to be able to adapt the shape of the photovoltaic module to that of the support. In general, during the design and production of an encapsulated photovoltaic module, also referred to as a laminated photovoltaic module, the aim is to provide the photovoltaic module with all of the following properties:
minimum thickness;
lightness in weight;
deformability;
flexibility;
translucency;
sealing;
reliability; and
sturdiness.

However, it was found that the ethylene vinyl acetate (EVA)-type or epoxy-type resins used to encapsulate the photovoltaic cells of the laminate tend to turn yellow due to their exposure to ultraviolet radiation, which reduces the conversion efficiencies over time of the laminate, in particular when these resins form a front encapsulation layer, i.e., the layer of the laminate intended to be traversed first by the light rays of the sun.

The use of a polyolefin-type encapsulation resin is known from US 2013/0133726, U.S. Pat. Nos. 9,312,425, 9,035,172, and WO 2014/081999. These documents specify that the polyolefins do not turn yellow in the course of being exposed to ultraviolet radiation, which makes it possible in particular to prevent losses in the conversion efficiency of the photovoltaic modules. However, the various photovoltaic modules described in said documents have a fairly limited shock resistance or resistance to deformations, which can be detrimental to the integrity of the cells and of these photovoltaic modules over time.

The aim of the present invention is to at least partially overcome the drawbacks of the prior art described above by providing a flexible laminate of which the conversion efficiencies and integrity do not deteriorate over time.

Another aim of the present invention is to provide a method for producing such a flexible laminate.

### SUMMARY OF THE INVENTION

In order to at least partially achieve at least one of the aforementioned aims, the present invention relates to a flexible laminate of photovoltaic cells, comprising at least:
a layer of interconnected photovoltaic cells; and
a front layer and a back layer for encapsulating the layer of photovoltaic cells, said front encapsulation layer and said back encapsulation layer sandwiching the layer of photovoltaic cells,
   the front encapsulation layer comprising at least one glass fiber fabric and at least a first encapsulation resin that comprises at least one polyolefin, and in that the back encapsulation layer comprises at least one glass fiber fabric and a second encapsulation resin.

The use of a polyolefin-based encapsulation resin, at least for the front encapsulation layer, makes it possible to prevent yellowing of said layer and thus prevent the reduction in the conversion efficiencies of this photovoltaic module. Furthermore, the combination of the encapsulation resin with a glass fiber fabric for the front encapsulation layer and for the back encapsulation layer makes it possible to impart shock resistance to the laminate and therefore to ensure the integrity of said laminate over time.

The flexible laminate according to the present invention may further have one or more of the following features taken alone or in combination.

The at least one polyolefin in the first encapsulation resin can be selected from linear polyolefins or branched polyolefins.

According to a particular embodiment, the polyolefin can be selected from polyethylene, branched polyethylene, linear low-density polyethylene, linear high-density polyethylene, or polypropylene.

The polyolefin can in particular be selected from ethylene-octene or ethylene-butene copolymers.

The first encapsulation resin can have a complex viscosity of less than 10,000 Pa·s at 90° C.

The at least one polyolefin of the first encapsulation resin can have a weight percentage of oxygen and nitrogen of less than 5% in its main chain or in its linear chain.

The first encapsulation resin can have a volume resistivity of at least 10¹⁵ Ω·cm.

The polyolefin of the first layer can comprise an antioxidant such as a hindered amine light stabilizer (HALS).

The polyolefin can have a density of between 0.83 and 0.93.

Alternatively or additionally, the polyolefin can have a hardness on the Shore A measurement scale of between 48 and 100.

Optionally, the polyolefin can have a hardness on the Shore D measurement scale of between 10 and 50.

Alternatively or additionally, the polyolefin can have a tensile strength of between 2 MPa and 30 MPa.

Optionally, the polyolefin can have a tensile elongation of greater than 300%, in particular between 600% and 850%.

The second encapsulation resin can be selected from ethylene vinyl acetate (EVA) resins, epoxy resins, or polyolefin resins.

The second encapsulation resin can have a complex viscosity of less than 10,000 Pa·s at 90° C.

The first encapsulation resin and the second encapsulation resin can have the same chemical composition.

The glass fiber fabric of the back encapsulation layer or of the front encapsulation layer can have a fiber density of between 50 g/m² and 500 g/m², in particular between 100 g/m² and 300 g/m².

The glass fiber fabrics of the front encapsulation layer and the back encapsulation layer are pre-impregnated with the first encapsulation resin and the second encapsulation resin, respectively.

The glass fibers making up the glass fiber fabrics have a diameter of between 0.01 mm and 0.1 mm.

The glass fibers can contain silanol functions.

The front encapsulation layer can have a transmittance of greater than or equal to 80%, preferably greater than 90%, for wavelengths between 315 nm and 1200 nm.

The flexible laminate can include a back sheet arranged in contact with the back encapsulation layer, said back sheet comprising one or more layers.

At least one layer of the back sheet can comprise a hydrophobic polymer.

The hydrophobic polymer can be a fluoropolymer selected from polyvinylidene fluorides (PVDF), polyvinyl fluorides (PVF), polytetrafluoroethylenes (PTFE), or ethylene tetrafluoroethylenes (ETFE).

The hydrophobic polymer can be selected from polypropylenes (PP), polyphenylene sulfides (PPS), polyesters, polycarbonates, polyphenylene oxides (PPO), polyethylene terephthalates (PET), polyurethanes, acrylics, or silicones.

The flexible laminate can have a transparent front layer arranged in contact with the front encapsulation layer, said front layer being designed to impart anti-fouling properties and/or anti-reflective properties and/or hydrophobic properties to the laminate.

The front layer can be formed by a film or a varnish.

The film of the front layer may consist of a material selected from polyvinylidene fluorides (PVDF), polyvinyl fluorides (PVF), ethylene tetrafluoroethylenes (ETFE), polyethylene terephthalates (PET), polyurethanes, acrylics, silicones, polycarbonates (PC), or polymethyl methacrylates (PMMA).

The varnish of the front layer can be a polymer-based varnish of the polyurethane, acrylic, polyester or silicone type.

The present invention also relates to a method for producing a flexible laminate as defined above, the method comprising the following steps:
preparing a stack of layers, comprising at least:
   a front encapsulation layer comprising at least one glass fiber fabric and at least a first encapsulation resin that comprises at least one polyolefin;
   a layer of photovoltaic cells; and
   a back encapsulation layer comprising a second encapsulation resin and a glass fiber fabric;
introducing the stack of layers into a lamination chamber of a lamination oven;
vacuum drawing in order to draw in the air inside the lamination chamber and between the different layers of the stack;
compressing the stack of layers to form the laminate;
heating the lamination chamber to a predetermined temperature in order to allow initiation of a polymerization reaction of the first encapsulation resin and of the second encapsulation resin;
ventilating the lamination chamber; and
removing the laminate from the lamination chamber.

The production method may further comprise one or more of the following features taken alone or in combination.

According to a particular embodiment, the glass fiber fabric of the back encapsulation layer may be impregnated with the second encapsulation resin during a pre-impregnation step prior to the step of preparing the stack of layers.

In one aspect, the back sheet may be laminated together with the stack of layers during the step of compressing the stack of layers.

According to this aspect, the stack of layers further comprises the back sheet arranged in contact with the back encapsulation layer, such that the back encapsulation layer is sandwiched between the back sheet and the layer of photovoltaic cells.

In another aspect, the back sheet can be arranged on the back encapsulation layer after the step of removing the flexible laminate from the lamination chamber.

According to one alternative, the front layer can be placed on the front encapsulation layer after the step of removing the flexible laminate from the lamination chamber.

After the step of removing the flexible laminate from the lamination chamber, the front layer and/or the back sheet can be arranged on the front encapsulation layer and on the back encapsulation layer, respectively, by one of the following techniques: dipping, printing, physical vapor deposition, chemical vapor deposition, coating, or gluing.

According to another alternative, the front layer can be laminated together with the stack of layers during the step of compressing the stack of layers.

According to this other alternative, the stack of layers further comprises the front layer arranged in contact with the front encapsulation layer, such that the front encapsulation layer is sandwiched between the front layer and the layer of photovoltaic cells.

### BRIEF DESCRIPTION OF THE DRAWINGS

Other features and advantages of the present invention will become apparent on reading the following description, provided by way of illustration and not by way of limitation, and the appended drawings, in which:

FIG. 1 is a schematic top view of a flexible laminate;

FIG. 2 is a schematic cross-sectional view of the flexible laminate of FIG. 1 according to a particular embodiment;

FIG. 3 is a schematic cross-sectional view of the flexible laminate of FIG. 1 according to one alternative;

FIG. 4 is a schematic cross-sectional view of the flexible laminate of FIG. 1 according to another alternative;

FIG. 5 is a schematic cross-sectional view of the flexible laminate of FIG. 1 according to yet another alternative; and

FIG. 6 is a schematic representation of a flowchart showing various steps of a method for producing the flexible laminate of FIG. 1.

### DETAILED DESCRIPTION OF THE INVENTION

Identical elements in the various figures are denoted by the same reference signs.

The following embodiments are examples. Although the description refers to one or more embodiments, this does not necessarily mean that each reference relates to the same embodiment, or that the features apply to only one embodiment. Simple features of different embodiments can also be combined and/or interchanged to provide other embodiments.

In the following description, particular elements or parameters can be listed, for example first element or second element, first parameter and second parameter, or first criterion and second criterion, etc. This is simple listing to differentiate and name elements that are similar but not identical and such names can be easily interchanged without departing from the scope of the present description. This listing does not imply an order in time to assess a given criterion.

In the following description, the term “front layer” is understood to mean the surface of the laminate exposed first to solar rays when the laminate is installed. Similarly, the term “back layer” is understood in the following description to mean the layer opposite the front layer, i.e., the surface which is impacted last by the solar rays during their passage through the flexible laminate when the laminate is installed.

Next, the term “polyolefin” is understood in the following description to mean a saturated synthetic aliphatic polymer resulting from the polymerization of an olefin, such as ethylene or its derivatives; such a polyolefin can also be referred to as polyalkene.

Furthermore, with reference to FIGS. 2 to 4, the different layers making up a laminate 1 are spaced apart from one another. This view is only intended to better identify the different layers. When the flexible laminate 1 is delivered, the different layers shown are in contact with one another.

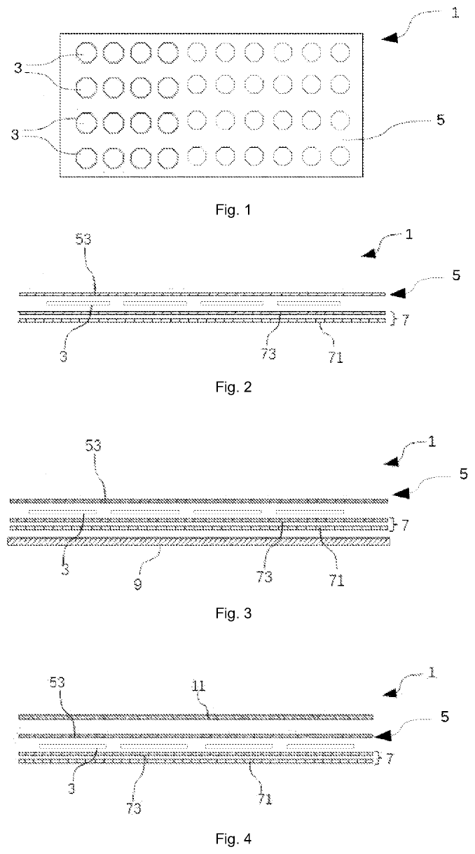

With reference to FIGS. 1 to 5, a flexible laminate 1 of photovoltaic cells is shown. The flexible laminate 1 comprises at least one layer of interconnected photovoltaic cells 3, and a front layer 5 and a back layer 7 for encapsulating the layer of photovoltaic cells 3. The front encapsulation layer 5 and the back encapsulation layer 7 sandwich the layer of photovoltaic cells 3.

The layer of photovoltaic cells 3 may be formed of photovoltaic cells made of silicon, for example monocrystalline or multicrystalline silicon, or of thin layers. Alternatively, other types of photovoltaic cells can also be used to form this layer of photovoltaic cells 3, for example organic photovoltaic cells.

The front encapsulation layer 5 comprises at least one glass fiber fabric 51 and at least a first encapsulation resin 53. So that the laminate 1 has good conversion efficiencies, the front encapsulation layer 5 has a transmittance of greater than or equal to 80%, preferably greater than 90%, for wavelengths between 315 nm and 1200 nm. It is necessary for this front encapsulation layer 5 to have a high transmittance for particular wavelengths of the solar spectrum, in particular the useful part of the solar spectrum for photovoltaic conversion, so as not to adversely affect the conversion efficiencies of the flexible laminate 1.

The first encapsulation resin 53 comprises at least one polyolefin. The use of a polyolefin in the front encapsulation layer 5 makes it possible to prevent said layer from yellowing and thus prevent the drop in the conversion efficiencies of the flexible laminate 1. In addition, the polyolefins are hydrophobic and demonstrate a high level of chemical inertness to solvents, acids and bases, which allows good protection of the encapsulated layer of photovoltaic cells 3 and contributes to the integrity of the flexible laminate 1 over time.

More particularly, the polyolefin can be selected from linear polyolefins or branched polyolefins. According to the various embodiments shown with reference to FIGS. 1 to 5, the polyolefin can be selected from polyethylene, branched polyethylene, linear low-density polyethylene, linear high-density polyethylene, or polypropylene. The polyolefin can in particular be selected from ethylene-octene or ethylene-butene copolymers.

Optionally, the polyolefin of the first encapsulation resin 53 can comprise an antioxidant such as a hindered amine light stabilizer (HALS). The presence of an antioxidant makes it possible to prevent oxidation of the polyolefin and allow said polyolefin to retain its various physical properties, in particular flexibility and tensile strength.

According to the particular embodiment of FIG. 1, the polyolefin of the first encapsulation resin 53 has a density of between 0.83 and 0.93. Such a density for the polyolefin makes it possible to limit the weight of the front encapsulation layer 5, making it possible in particular to limit the weight of the flexible laminate 1. Furthermore, this polyolefin has a hardness on the Shore A measurement scale of between 48 and 100 and a hardness on the Shore D measurement scale of between 10 and 50. According to the definition of the ISO 868 and 7619 standards, the Shore A measurement scale is used for soft materials and the Shore D measurement scale is used for hard materials. Such hardnesses for the polyolefin make it possible to protect the photovoltaic cells 3 from the shocks or impacts that said cells may have to be subjected to once this flexible laminate 1 has been installed or even during the transport or storage of said laminate. Furthermore, the polyolefin forming the first encapsulation resin 53 has a tensile strength of between 2 and 30 MPa and a tensile elongation of greater than 300%, in particular between 600% and 850%. Such tensile properties allow the front encapsulation layer 5 to be deformable and to impart flexibility properties to the laminate 1, as will be explained in more detail below.

Furthermore, the front encapsulation layer 5 comprises at least one glass fiber fabric 51 and a first encapsulation resin 53. Similarly, the back encapsulation layer 7 comprises at least one glass fiber fabric 71 and a second encapsulation resin 73.

The second encapsulation resin 73 can be selected from ethylene vinyl acetate (EVA) resins, epoxy resins, polyester resins, polyurethane resins, acrylic resins, or polyolefin resins. The use of EVA resins or epoxy resins for the second encapsulation resin 73 is not problematic because this back encapsulation layer 7 can be traversed by light rays after the layer of photovoltaic cells 3. According to a particular embodiment, the first encapsulation resin 53 and the second encapsulation resin 73 can have the same chemical composition. This makes it possible in particular to overcome the problems of chemical compatibility between this first encapsulation resin 53 and this second encapsulation resin 73 which could adversely affect their adhesion and therefore the encapsulation of the layer of photovoltaic cells 3 of the flexible laminate 1, and to simplify industrial logistics.

Moreover, the first encapsulation resin 53 and the second encapsulation resin 73 can have a complex viscosity of less than 10,000 Pa·s at 90° C. The value of the complex viscosity is an important criterion for the performance and reliability of the flexible laminate 1. If said value is too large, the first encapsulation resin 53 and the second encapsulation resin 73 will not be able to easily diffuse into the fibers of the glass fiber fabric 51, 71 or between the photovoltaic cells and therefore ensure the transparency of the back encapsulation layer 7 or contact with the photovoltaic cells 3, which could be detrimental to the integrity of the flexible laminate 1.

In addition, and also in order to avoid the risk of cracks in the first encapsulation resin 53, and in the second encapsulation resin 73 when said second encapsulation resin is made from a polyolefin, the polyolefin has a weight percentage of oxygen and nitrogen of less than 5% in its main chain or in its linear chain, i.e., the combined weight percentage of oxygen and nitrogen in the polyolefin is less than 5%. In addition, when the second encapsulation resin 73 is a polyolefin, said resin can have the same physical characteristics as that of the first encapsulation resin 53 mentioned above.

Furthermore, the first encapsulation resin 53 and the second encapsulation resin 73 have a volume resistivity of at least 10¹⁵ Ω·cm. This first encapsulation resin 53 and this second encapsulation resin 73 therefore correspond to insulators. Indeed, to prevent short circuits between the different photovoltaic cells of the layer of photovoltaic cells 3, it is necessary for the first encapsulation resin 53 and the second encapsulation resin 73 to be insulators because they are in contact with the photovoltaic cells 3 of the flexible laminate 1.

Furthermore, the glass fiber fabric 71 of the back encapsulation layer 7 has a fiber density of between 50 g/m² and 500 g/m², in particular between 100 g/m² and 300 g/m². The density of the glass fiber fabric allows the second encapsulation resin 73 to diffuse through this glass fiber fabric 71 during the method for producing this flexible laminate 1 and also to protect the layer of photovoltaic cells 3 from possible shocks, impacts, or deformations that it could be subjected to during the transport of the flexible laminate 1, its installation, or during its operation as this laminate 1 is intended to be installed outdoors. Thus, this glass fiber fabric 71 makes it possible to ensure the physical integrity of the flexible laminate 1 over time.

This glass fiber fabric 71 can for example be made of E-type glass, of ECR-type glass, or even of AR-type glass. These different glasses exhibit good resistance to heat and to chemical attack, good thermal stability and satisfactory tensile and compressive strength properties, to allow their use as a component of the flexible laminate 1.

Furthermore, the glass fibers making up the glass fiber fabric 71 can have a diameter of between 0.01 mm and 0.1 mm.

Furthermore, the glass fibers making up the glass fiber fabric 71 can have silanol functions, in particular when the second encapsulation resin 73 is a polyolefin. The silanol groups have good chemical affinity with the polyolefins, which makes it possible, inter alia, to reinforce the cohesion of the second encapsulation resin 73 with the glass fiber fabric 71 and therefore with the photovoltaic cells 3.

According to a particular embodiment, the glass fiber fabrics 51, 71 are pre-impregnated with the first encapsulation resin 53 and the second encapsulation resin 73, respectively. This makes it possible to reduce the duration of the production of such a flexible laminate 1 and more precisely to reduce the duration of the production method 100 described in more detail below.

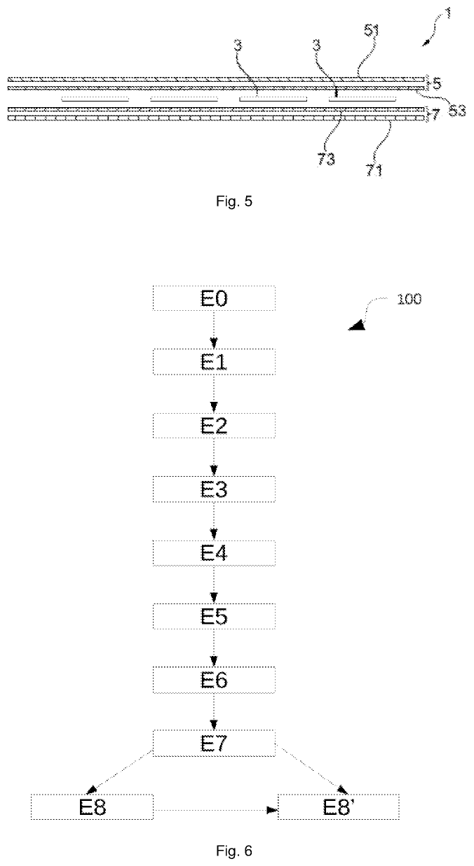

As shown in FIG. 5, the front encapsulation layer 5 of the flexible laminate 1 includes at least one glass fiber fabric 51. This glass fiber fabric 51 can have the same physicochemical properties as the glass fiber fabric 71 of the back encapsulation layer 7 described above. Furthermore, the presence of this glass fiber fabric 51 also helps improve the resistance of this flexible laminate 1 to the impacts that it may have to be subjected to when it is installed, for example on the roof of a building.

With reference to FIGS. 2 to 4, the front encapsulation layer 5 and the back encapsulation layer 7 have a thickness which may be between 0.05 mm and 3 mm. Such a thickness of the front encapsulation layer 5 and the back encapsulation layer 7 makes it possible to obtain a flexible laminate 1 of small thickness, which makes it possible in particular to minimize costs linked to its storage or to its transport. Furthermore, the various constituent elements of this flexible laminate 1 have light weights, which makes it possible to obtain a flexible laminate 1 of low weight, typically less than or equal to 5 kg/m². For example, for a laminate having a length of 1200 mm and a width of 526 mm, such a flexible laminate 1 has a weight of 3.16 kg, which represents a weight per unit area of 5.00 kg/m², or for a laminate having a length of 2030 mm and a width of 800 mm, such a flexible laminate 1 has a weight of 6.9 kg, which represents a weight per unit area of 4.24 kg/m². In addition, such a laminate 1 has flexibility properties which make it possible to facilitate its transport as well as its installation. Flexible is intended here to mean an element which, when a particular radius of curvature is applied, does not lose its physical integrity or its electrical performance. More particularly, a flexible element here is an element which does not crack when a particular radius of curvature is applied thereto, and more particularly, within the meaning of the present description, the element has to withstand a radius of curvature of 100 cm without damage.

According to the particular embodiment of FIGS. 1, 2 and 5, the flexible laminate 1 only has the front encapsulation layer 5 and the back encapsulation layer 7 and the layer of photovoltaic cells 3.

According to one alternative shown with reference to FIG. 3, the flexible laminate 1 may include a back sheet 9 arranged in contact with the back encapsulation layer 7. The back sheet 9 can comprise one or more layers. This back sheet may impart additional properties to the flexible laminate 1 or enhance some of the properties of the first encapsulation resin 53 and second encapsulation resin 73. For example, at least one layer of the back sheet 9 comprises a hydrophobic polymer in order to improve the moisture resistance of the flexible laminate 1. This hydrophobic polymer can be a fluoropolymer selected from polyvinylidene fluorides (PVDF), polyvinyl fluorides (PVF), polytetrafluoroethylenes (PTFE), or ethylene tetrafluoroethylenes (ETFE), or be selected from polypropylenes (PP), polyphenylene sulfides (PPS), polyesters, polycarbonates, polyphenylene oxides (PPO), polyethylene terephthalates (PET), polyurethanes, acrylics, or silicones.

According to another alternative, shown with reference to FIG. 4, the flexible laminate 1 may have a transparent front layer 11 arranged in contact with the front encapsulation layer 5. The term transparent is understood here to mean the fact that this front layer 11 has a transmittance of greater than or equal to 80%, preferably greater than or equal to 90%, for wavelengths between 315 nm and 1200 nm. The front layer 11 is designed to impart anti-fouling properties and/or anti-reflective properties and/or hydrophobic properties to the flexible laminate 1, for example. The front layer 11 can be formed by a film or a varnish, for example. The film of the front layer 11 can be made of a material selected from polyvinylidene fluorides (PVDF), polyvinyl fluorides (PVF), ethylene tetrafluoroethylenes (ETFE), polyethylene terephthalates (PET), polyurethanes, acrylics, silicones, polycarbonates (PC), or polymethyl methacrylates (PMMA). Furthermore, the varnish of the front layer 11 can be a polymer-based varnish of the polyurethane, acrylic, polyester or silicone type.

Furthermore, according to an alternative not shown here, the flexible laminate 1 can have the back sheet 9 and the front layer 11.

With reference to the various particular embodiments shown with reference to FIGS. 2 to 4, the presence of the back sheet 9 or of the front layer 11 does not adversely affect the flexibility properties of the flexible laminate 1. In addition, this back sheet 9 or this front layer 11 have a small thickness, which makes it possible, inter alia, to retain a flexible laminate 1 of which the thickness may remain less than 5 mm and also having a weight of less than or equal to 5 kg/m² for a laminate having dimensions as stated above.

With reference to FIG. 6, a flow chart outlining a method 100 for producing the flexible laminate 1 described above is shown.

The production method 100 comprises a step E1 of preparing a stack of layers comprising at least one front encapsulation layer 5, a layer of photovoltaic cells 3, and a back encapsulation layer 7 as described above.

The production method 100 then implements a step E2 of introducing the stack of layers into a lamination chamber of a lamination oven, then a step E3 of vacuum drawing in order to draw in the air inside the lamination chamber and between the different layers of the stack. This vacuum drawing step E3 can for example be carried out using a vacuum pump. At the end of this vacuum drawing step E3, the pressure inside the lamination chamber may be less than 20 mbar, in particular approximately 1 mbar. The evacuation of air from inside the lamination chamber makes it possible in particular to prevent the formation of bubbles in the first encapsulation resin 53 and the second encapsulation resin 73 during their polymerization reaction. This vacuum drawing step E3 may be subject to preheating in order to degas the volatile compounds of the flexible laminate 1 more quickly. When such preheating is carried out, the temperature inside the lamination chamber remains lower than the polymerization temperature of the first encapsulation resin 53 and the second encapsulation resin 73. For example, the temperature inside the lamination chamber during this preheating step can be approximately 50° C.

Once this pressure has been reached inside the lamination chamber, the production method 100 implements a step E4 of compressing the stack of layers in order to form the flexible laminate 1. In order to do this, the lamination chamber can have a movable plate designed to compress the stack of layers.

Once this pressure has been applied to the stack of layers, the production method 100 implements a step E5 of heating the lamination chamber to a predetermined temperature in order to allow initiation of a polymerization reaction of the first encapsulation resin 53 and the second encapsulation resin 73. This predetermined temperature corresponds to the polymerization temperature of the selected encapsulation resin(s). Furthermore, during this heating step E5, the vacuum pump remains in operation so as to draw in the fumes and vapors which could be produced during the polymerization reaction of the first encapsulation resin 53 and the second encapsulation resin 73.

After a predetermined period, for example approximately 5 minutes, the vacuum pump is stopped and the method implements a step E6 of ventilating the lamination chamber, then a step E7 of removing the obtained laminate 1 from the lamination chamber.

According to a particular embodiment and optionally, the glass fiber fabric 71 of the back encapsulation layer 7 and the glass fiber fabric 51 of the front encapsulation layer 5 can be impregnated with the second encapsulation resin 73 and the first encapsulation resin 53, respectively. In order to do this, the production method 100 can include a pre-impregnation step E0 prior to the step E1 of preparing the stack of layers. It may be possible to have glass fiber fabrics 51, 71 already impregnated with the first encapsulation resin 53 or the second encapsulation resin 73. It is thus possible to reduce the time required to carry out this production method 100.

In order to obtain the flexible laminates 1 shown with reference to FIGS. 3 and 4, the back sheet 9 and/or the front layer 11 can be laminated together with the stack of layers during the step E4 of compressing the stack of layers when the constituent materials of the back sheet 9 or of the front layer 11 have melting temperatures which may be sufficient to withstand the step E5 of heating the stack of layers, or to ensure that these constituent materials do not undergo thermal degradation linked to this heating step E5.

For this purpose, the stack of layers may further comprise the back sheet 9 arranged in contact with the back encapsulation layer 7, such that the back encapsulation layer 7 is sandwiched between the back sheet 9 and the layer of photovoltaic cells 3, or the stack of layers may further comprise the front layer 11 arranged in contact with the front encapsulation layer 5, such that the front encapsulation layer 5 is sandwiched between the front layer 11 and the layer of photovoltaic cells 3.

Alternatively, the back sheet 9 can be arranged on the back encapsulation layer 7 during a step E8 of depositing the back layer following the step E7 of removing the flexible laminate 1 from the lamination chamber, or the front layer 11 can be arranged on the front encapsulation layer 5 during a step E8′ of depositing the front layer following the step E7 of removing the flexible laminate 1 from the lamination chamber.

According to this alternative, after the step E7 of removing the flexible laminate 1 from the lamination chamber, the steps of depositing the back layer E8 or the front layer E8′ can be carried out by one of the following techniques: dipping, printing, physical vapor deposition, chemical vapor deposition, coating, or gluing.

The particular embodiments described above are given by way of illustration and not by way of limitation. It is quite possible for a person skilled in the art to modify the thickness of the front encapsulation layer 5 and the back encapsulation layer 7 without departing from the scope of the present invention. Moreover, a person skilled in the art will be able to use other constituent materials of the front layer 11, of the back sheet 9, of the second encapsulation resin 73, and of the glass fiber fabric 71 without departing from the present invention. Similarly, a person skilled in the art may use other polyolefins for the first encapsulation resin 53 than the various specific polyolefins described in this description, without departing from the scope of the present invention.

Thus, obtaining a flexible laminate 1 of which losses in conversion efficiency are prevented and of which the physical integrity over time is ensured is possible due to the flexible laminate 1 comprising, at least for its front encapsulation layer 5, a first encapsulation resin 53 that comprises a polyolefin as described above.

1. A flexible laminate of photovoltaic cells, comprising at least:
a layer of interconnected photovoltaic cells; and
a front layer and a back layer for encapsulating the layer of photovoltaic cells, said front encapsulation layer and said back encapsulation layer sandwiching the layer of photovoltaic cells,
characterized in that the front encapsulation layer comprises at least one glass fiber fabric and at least a first encapsulation resin that comprises at least one polyolefin, and in that the back encapsulation layer comprises at least one glass fiber fabric and a second encapsulation resin.

2. The flexible laminate according to the preceding claim, characterized in that the at least one polyolefin in the first encapsulation resin is selected from linear polyolefins or branched polyolefins.

3. The flexible laminate according to claim 1, characterized in that the first encapsulation resin has a complex viscosity of less than 10,000 Pa·s at 90° C.

4. The flexible laminate according to claim 1, characterized in that the at least one polyolefin of the first encapsulation resin has a weight percentage of oxygen and nitrogen of less than 5% in its main chain or in its linear chain.

5. The flexible laminate according to claim 1, characterized in that the first encapsulation resin has a volume resistivity of at least 10¹⁵ Ω·cm.

6. The flexible laminate according to claim 1, characterized in that the first encapsulation resin has a transmittance of greater than or equal to 80% for wavelengths between 315 nm and 1200 nm.

7. The flexible laminate according to claim 1, characterized in that the second encapsulation resin is selected from ethylene vinyl acetate (EVA) resins, epoxy resins, or polyolefin resins.

8. The flexible laminate according to claim 1, characterized in that the glass fiber fabric of the front encapsulation layer and the back encapsulation layer has a fiber density of between 50 g/m² and 500 g/m².

9. The flexible laminate according to claim 1, characterized in that the glass fiber fabric of the front and back encapsulation layers is pre-impregnated with the first and the second encapsulation resins, respectively.

10. A method for producing a flexible laminate according to claim 1, characterized in that said method comprises the following steps:
preparing a stack of layers comprising at least:
a front encapsulation layer comprising at least one glass fiber fabric and at least a first encapsulation resin that comprises at least one polyolefin;
a layer of photovoltaic cells; and
a back encapsulation layer comprising a second encapsulation resin and a glass fiber fabric;
introducing the stack of layers into a lamination chamber of a lamination oven;
vacuum drawing in order to draw in the air inside the lamination chamber and between the different layers of the stack;
compressing the stack of layers;
heating the lamination chamber to a predetermined temperature in order to allow initiation of a polymerization reaction of the first encapsulation resin and of the second encapsulation resin;
ventilating the lamination chamber; and
removing the laminate from the lamination chamber.

11. The production method according to claim 10, characterized in that the glass fiber fabric of the back encapsulation layer is impregnated with the second encapsulation resin during a pre-impregnation step prior to the step of preparing the stack of layers.
